(19) United States
(12) Patent Application Publication
(10) Pub. No.: US 2013/0027232 A1
(43) Pub. Date: Jan. 31, 2013

(54) ANALOG-TO-DIGITAL CONVERTERS AND ANALOG-TO-DIGITAL CONVERSION METHODS

(71) Applicants: Yingyi LIU, Hefei City (CN); Yu-Kai CHOU, Hsinchu City (TW); Kun LAN, Hefei City (CN)

(72) Inventors: Yingyi LIU, Hefei City (CN); Yu-Kai CHOU, Hsinchu City (TW); Kun LAN, Hefei City (CN)

(73) Assignee: MEDIATEK SINGAPORE PTE. LTD., Singapore (SG)

(21) Appl. No.: 13/560,173

(22) Filed: Jul. 27, 2012

Related U.S. Application Data
(60) Provisional application No. 61/513,144, filed on Jul. 29, 2011.

(30) Foreign Application Priority Data
Oct. 14, 2011 (CN) 201110312894.4

(51) Int. Cl. H03M 1/12; H03M 1/68

(52) U.S. Cl. 341/110; 341/156

(57) ABSTRACT

An analog-to-digital converter is provided and comprises a most significant bit (MSB) conversion module, a successive approximation register analog-to-digital converter (SAR ADC) module, and an operation module. The MSB conversion module receives an analog signal to be converted, and converts the analog signal to an MSB with M bits, and obtains a redundancy signal. The SAR ADC module is coupled to the MSB conversion module. The SAR ADC receives the redundancy signal and processes the redundancy signal to be a least significant bit (LSB) with N bits. The operation module is coupled to the MSB conversion module and the SAR ADC module. The operation module receives the MSB with the M bits and the LSB with the N bits and generates a first digital signal with (M+N) bits. Each of M and N is positive, and (M+N) is a positive integer.

### CROSS REFERENCE TO RELATED APPLICATIONS

This application claims the benefit of U.S. Provisional Application No. 61/513,144, filed on Jul. 29, 2011, the contents of which are incorporated herein by reference.

This Application claims priority of China Patent Application No. 201110312894.4, filed on Oct. 14, 2011, the entirety of which is incorporated by reference herein.

### BACKGROUND OF THE INVENTION

1. Field of the Invention

The disclosure relates to signal processing devices and methods, and more particularly to an analog-to-digital converter and an analog-to-digital conversion method.

2. Description of the Related Art

Recently, with rapid development of digital processing techniques, signal processing tasks, such as filtering, frequency conversion, and modulation/demodulation, are performed for digital signals. Analog-to-digital converters serve as interfaces between analog signals and digital signals in consumer electronic products, such as televisions and mobile devices.

Successive approximation register analog-to-digital converters (SAR ADCs) are a common conversion structure in applications with middle or high resolution. SAR ADCs use a series of stages to convert analog voltages to digital bits. Each stage compares an analog voltage with a reference voltage to generate a digital bit. A conventional SAR DAC usually comprises a capacitive digital-to-analog converter (CDAC) using a large number of capacitors to enhance matching accuracy. For example, in a 10-bit SAR ADC, a CDAC requires 2¹⁰ (i.e. 1024) capacitors. Thus, an SAR ADC with high matching accuracy occupies a large area and has a high cost.

### BRIEF SUMMARY OF THE INVENTION

An exemplary embodiment of an analog-to-digital converter comprises a most significant bit (MSB) conversion module, a successive approximation register analog-to-digital converter (SAR ADC) module, and an operation module. The MSB conversion module receives an analog signal to be converted, and converts the analog signal to be converted to an MSB with M bits, and generates a redundancy signal. The SAR ADC module is coupled to the MSB conversion module. The SAR ADC receives the redundancy signal and generates a least significant bit (LSB) with N bits. The operation module is coupled to the MSB conversion module and the SAR ADC module. The operation module receives the MSB with the M bits and the LSB with the N bits and generates a digital signal with (M+N) bits. Each of M and L is positive, and (M+N) is also a positive integer.

An exemplary embodiment of an analog-to-digital conversion method comprises the step of: receiving an analog signal to be converted, and converting the analog signal to a most significant bit (MSB) with M bits, and generating a redundancy signal; receiving the redundancy signal and processing the redundancy signal to generate a least significant bit (LSB) with N bits; and receiving the MSB with M bits and the LSB with N bits and generating a digital signal with (M+N) bits, wherein each of M and L is positive, and (M+N) is a positive integer.

Another exemplary embodiment of an analog-to-digital converter comprises a first conversion module, a second conversion module, and an operation module. The first conversion module is configured to receive an analog signal to be converted and convert the analog signal to a most significant bit (MSB) with M bits, and also configured to generate a redundancy signal according to the MSB and the analog signal. The second conversion module is coupled to the first conversion module, and configured to receive the redundancy signal and generate a least significant bit (LSB) with N bits. The operation module is coupled to the first conversion module and the second conversion module, and configured to combine the MSB with the M bits and the LSB with the N bits, to generate a digital signal with (M+N) bits, wherein each of M and N is positive, and (M+N) is a positive integer.

According to the analog-to-digital converter and the analog-to-digital conversion method of the above embodiments, an analog signal to be converted is processed by two procedures. For example, an MSB with M bits is generated in advance, and then an LSB with N bits is generated. For a (M+N)-bit analog-to-digital converter, the number of capacitors used by the (M+N)-bit analog-to-digital converter is decreased to 2^{N} from 2^{N+M}, thereby achieving a high resolution analog-to-digital conversion and decreasing the size and cost of the (M+N)-bit analog-to-digital converter.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 shows an exemplary embodiment of an analog-to-digital converter (ADC);

FIG. 2 shows an exemplary embodiment of an MSB conversion module in the ADC of FIG. 1;

FIG. 3 shows another exemplary embodiment of an MSB conversion module in the ADC of FIG. 1;

FIG. 4 shows further another exemplary embodiment of an MSB conversion module in the ADC of FIG. 1; and

FIG. 5 shows an exemplary embodiment of an analog-to-digital conversion method.

### DETAILED DESCRIPTION OF THE INVENTION

The following description is made for the purpose of illustrating the general principles of the disclosure and should not be taken in a limiting sense. The scope of the disclosure is best determined by reference to the appended claims.

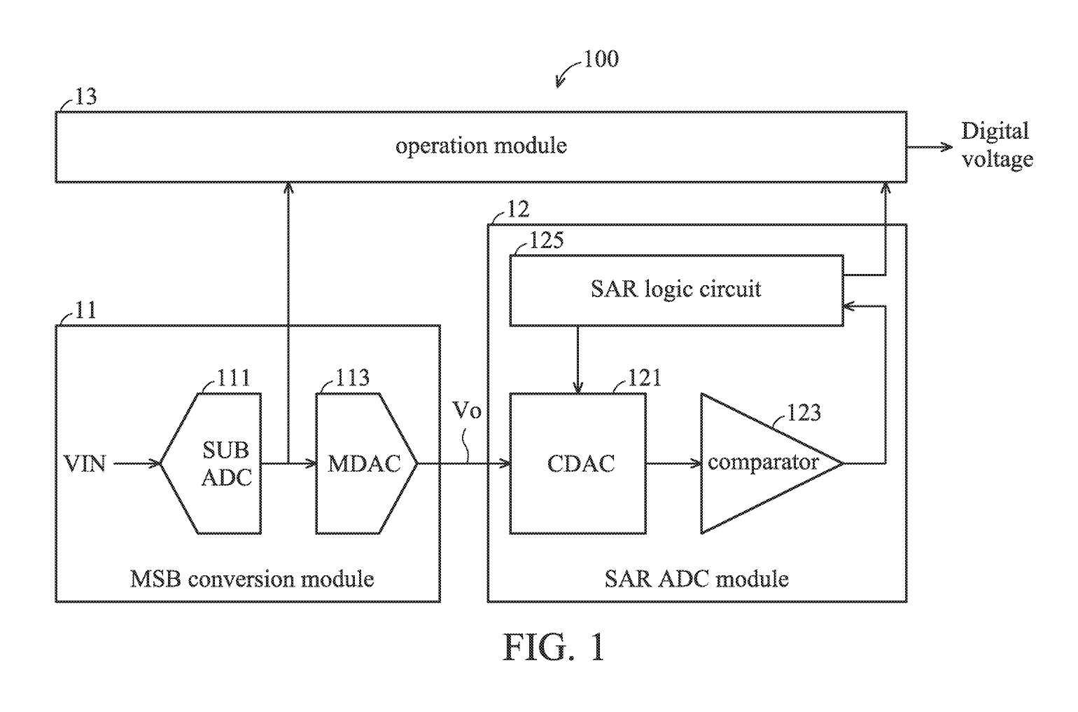

Analog-to-digital converter (ADC) modules are provided. In an exemplary embodiment of an ADC module in FIG. 1, an ADC 100 comprises a most significant bit (MSB) conversion module 11, a successive approximation register analog-to-digital converter (SAR ADC) module 12, and an operation module 13.

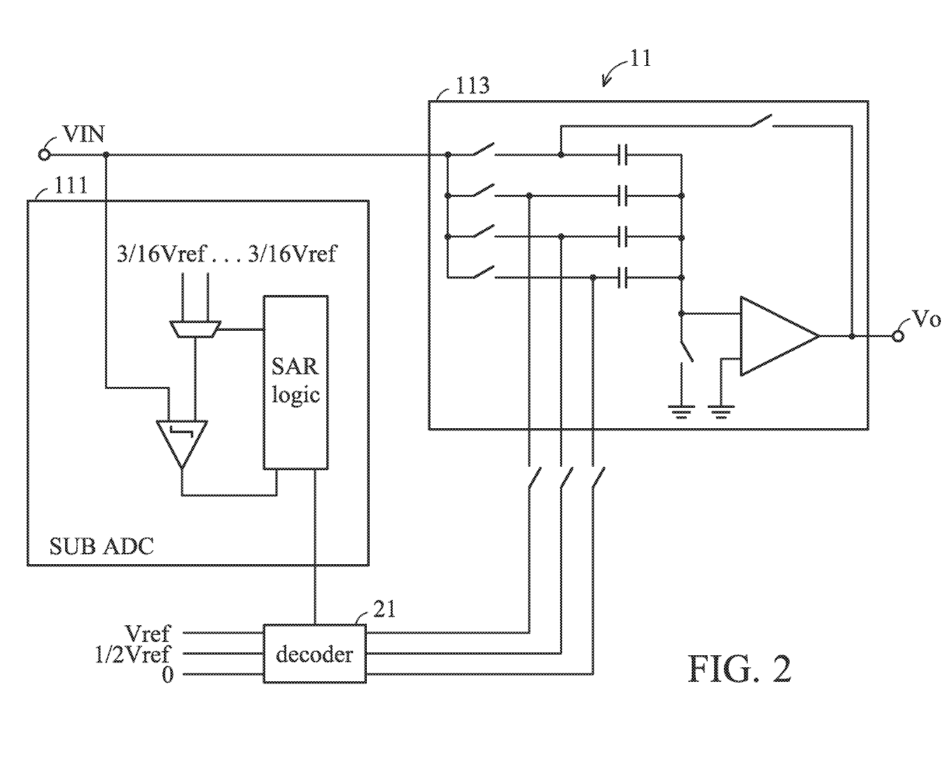

FIG. 2 shows an exemplary embodiment of the MSB conversion module 11. The MSB conversion module 11 receives an analog voltage to be converted and performs a conversion process to the analog voltage to generate a most significant bit (MSB) with M bits and obtain a redundancy signal. In the embodiment, the redundancy signal is a redundancy analog voltage V_{O}. The MSB conversion module 11 comprises a sub analog-to-digital converter (SUB ADC) 111 and a multiply digital-to-analog converter (MDAC) 113. The SUB ADC 111 is used to generate a digital signal with M bits. The MDAC 113 is coupled to the SUB ADC 111. In the embodiment, the SUB ADC 111 is implemented by an SAR ADC.

The SAR ADC module 12 is coupled to the MSB conversion module 11 to receive the redundancy signal (V_{O}). In this embodiment, the SAR ADC module 12 is coupled to the MSB conversion module 11 in series. The SAR ADC module 12 performs a signal process to the redundancy signal to generate a least significant bit (LSB) with N bits.

The operation module 13 is coupled to the MSB conversion module 11 and the SAR ADC module 12, to receive the MSB with the M bits and the LSB with N bits, respectively. The operation module 13 generates a digital signal with (M+N) bits according to the MSB with the M bits and the LSB with the N bits. Each of M and L is in a positive numerical value which can be integer or decimal fraction, and (M+N) is a positive integer. The operation module 13 is implemented by an adder-subtractor in this embodiment.

When the ADC 100 is activated, an analog voltage VIN is input to the SUB ADC 111. The SUB ADC 111 processes the analog voltage VIN according to a predetermined predetermined voltage, such as 3/16Vref, 5/16Vref, 7/16Vref, 9/16Vref, 11/16Vref, and 13/16Vref. Then, the SUB ADC 111 transmits the processed results to a decoder 21, and the decoder 21 decodes the processed results to generate a digital signal with 3 bits. In the embodiment, when the digital signal with 3 bits comprises one bit for correction, an MSB with 2.5 bits is generated. The MSB with 2.5 bits decoded by the decoder 21 is transmitted to the operation module 13 (see FIG. 1) and the MDAC 113. Accordingly, the MDAC 113 generates the redundancy analog voltage V_{O} according to the MSB with 2.5 bits and the analog voltage VIN.

The SAR ADC module 12 comprises a capacitive digital-to-analog converter (CDAC) 121, a comparator 123, and an SAR logic circuit 135. The CDAC 121 is coupled to the SAR logic circuit 125 and the MDAC 113. The comparator 123 is coupled between the CDAC 121 and the SAR logic circuit 125. An output terminal of the SAR logic circuit 125 is coupled to the operation module 13 and outputs the LSB with the N bits to the operation module 13. The SAR logic circuit 125 controls the CDAC 121 to operate according to a control signal. In this embodiment, the control signal is an external signal. The CDAC 121 performs a subtraction operation to a predetermined voltage and the redundancy signal (the redundancy analog voltage Vo), and outputs a number of operation results. The comparator 123 compares a reference signal with the operation results output from the CDAC 121 and determines whether the operation results is in the range defined by the reference signal. The comparator 123 then outputs the comparison results to the SAR logic circuit 125, so that the SAR logic circuit 125 converts the comparison results to the LSB with the N bits. In this embodiment, the number of capacitors used by the CDAC 121 is 2^{N}, wherein N represents the bit number of LSB.

According to the analog-to-digital conversion performed by the ADC 100, the analog voltage VIN is input to the SUB ADC 111 of the MSB conversion module 11, and the SUB ADC 111 performs a rough analog-to-digital conversion to the analog voltage VIN to generate the digital signal with the M bits. The MDAC 113 in the MSB conversion module 11 generates an analog voltage level corresponding to the quantified digital signal with the M bits and then subtracts the analog voltage level from the analog voltage VIN to generate the redundancy analog voltage V_{O}. The MSB conversion module 11 outputs the digital signal with the M bits to the operation module 13 and further transmits the redundancy analog voltage V_{O} to the SAR ADC module 12. The accuracy of the SAR ADC module 12 is N bits. In a preferred embodiment, N is greater than M. The SAR ADC module 12 receives the redundancy analog voltage V_{O} from the MDAC 113 and performs an analog-to-digital conversion to the redundancy analog voltage V_{O} to obtain a digital signal with N bits. The SAR ADC module 12 transmits the digital signal with N bits to the operation module 13. The operation module 13 combines the digital signal with the M bit, which is generated from the MSB conversion module 11 by performing the rough analog-to-digital conversion to the analog voltage VIN, and the digital signal with the N bits, which is generated from the SAR ADC module 12 by performing a fine analog-to-digital conversion. That is, the digital signal with the M bits output from the MSB conversion module 11 serves as an MSB of a digital signal, and the digital signal with the N bits output from the SAR ADC module 12 serves as an LSB of the digital signal. The operation module 13 combines the MSB of the digital signal with the M bits and the LSB of the digital signal with the N bits to form a high accuracy digital signal with the (M+N) bits for outputting. In this embodiment, the operation module 13 adds the MSB with the M bits to the LSB with the N bits.

In the ADC 100 of the above embodiment, the SAR ADC module 12 comprising the CDAC 121, the comparator 123, and the SAR logic circuit 125 is given as an example. However, one skilled in the art understands that the SAR ADC having other structures can be used to implement the SAR ADC module 12.

According to the ADC 100 of the above embodiment, by additionally disposing the MSB conversion module 11 to generate one or more MSBs before the SAR ADC module 12, the SAR ADC module 12 is required to generate only an LSB with N bits for a (M+N)-bit ADC. Thus, compared with the conventional SAD ADC, the number of capacitors used by the SAR ADC module 12 is decreased to 2^{N} from 2^{N+M}, thereby achieving a high resolution analog-to-digital conversion and decreasing the size and cost of the ADC 100.

Moreover, in the ADC 100 of the above embodiment, the MSB conversion module 11 comprises the SUB ADC 111 generating the digital signal with the M bits and the MDAC 113 coupled to the SUB ADC 111. However, one skilled in the art understands that the MSB conversion module 11 may be implemented by pipelined ADCs with at least two stages. The pipelined ADC of each stage comprises a SUB ADC for generating a digital signal with one bit and an MDAC coupled to the SUB ADC. The MSB conversion module 11 implemented by pipelined ADCs with three stages is given as an example. The pipelined ADC of the first stage generates a digital signal with one bit according to an input analog voltage and outputs the digital signal to an operation module. Then, a MDAC coupled to a SUB ADC generates a redundancy voltage according to the quantified result generated by the SUB ADC and transmits the redundancy voltage to a SUB ADC in the pipelined ADC of the next stage. The same data pipelining is performed repeatedly until each of the SUB ADCs in the pipelined ADCs with the three stages performs an analog-to-digital conversion to the analog voltage once and the SUB ADCs in the three stages transmit a digital signal with 3 bits to an operation module jointly.

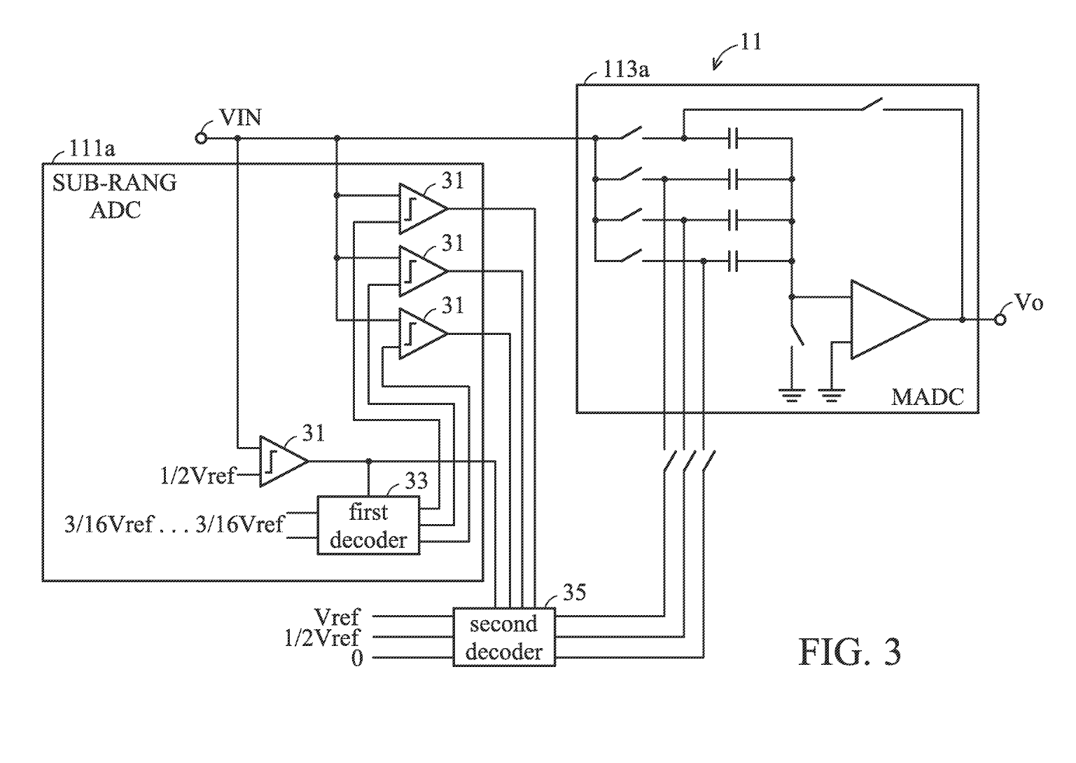

FIG. 3 shows another exemplary embodiment of the MSB conversion module 11. The SUB ADC in the MSB conversion module 11 may be implemented by a sub-range ADC 111a. In this embodiment, the analog voltage VIN in input to the sub-range ADC. A plurality of comparators 31 and a first decoder 33 in the sub-range ADC process the analog voltage VIN according to a predetermined predetermined voltage and transmits the processed results to a second decoder 33. The second decoder 33 performs a decoding operation to the processed results from the sub-range ADC to generate an MSB with 2.5 bits. The MSB with 2.5 bits decoded by the second decoder 35 is transmitted to the operation module (see FIG. 1) and the MDAC 113a. Accordingly, the MDAC 113a generates the redundancy voltage V_{O} according to the MSB with 2.5 bits and the analog voltage VIN.

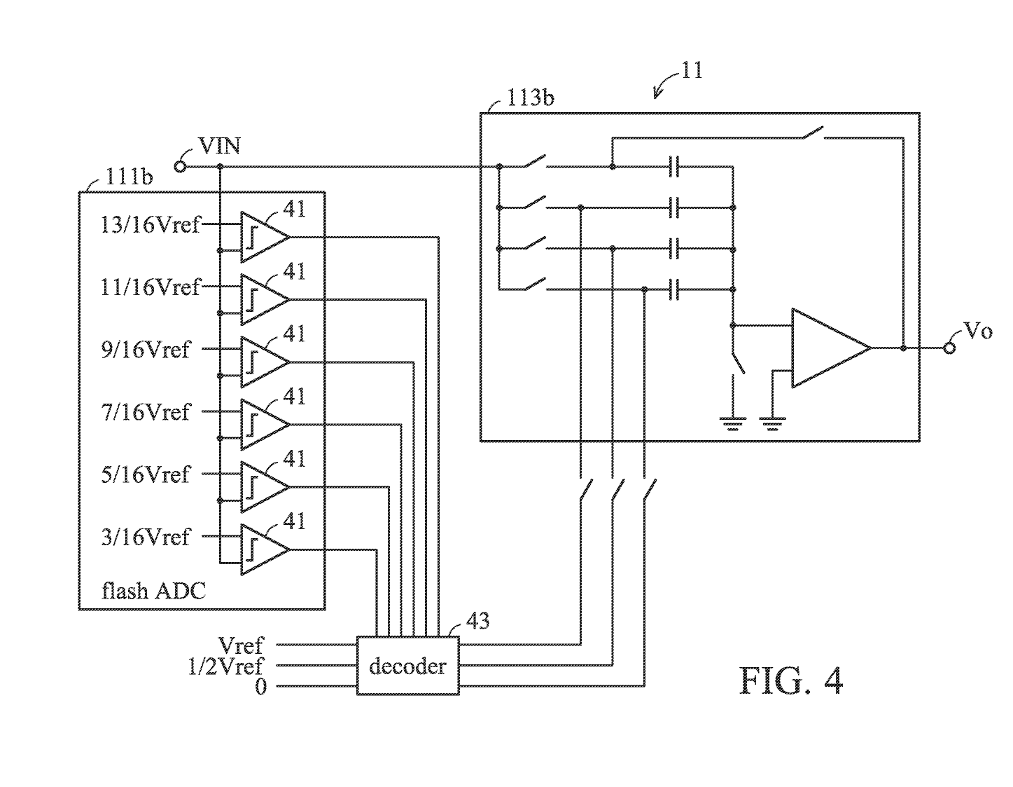

FIG. 4 shows further another exemplary embodiment of the MSB conversion module 11. Referring to FIG. 4, the SUB ADC in the MSB conversion module 11 may be implemented by a flash ADC 111b. When it is desired to generate an MSB with 2.5 bits, a flash ADC comprising six comparators 41 is used. The six comparators 41 process the input analog voltage VIN according to predetermined voltages 3/16Vref, 5/16Vref, 7/16Vref, 9/16Vref, 11/16Vref, and 13/16Vref respectively and transmit the processed result to a decoder 43. The decoder 43 processes the signals from the six paths according to the predetermined voltages Vref and ½Vref and 0V to generate an MSB with 2.5 bits and transmits the MSB with 2.5 bits to the operation module (see FIG. 1) and the MDAC 113b. Accordingly, the MDAC 113b generates the redundancy voltage V_{O} according to the MSB with 2.5 bits and the analog signal VIN.

In the ADCs of the above embodiments, N is greater than 6.

According to the above embodiments, when the SAR ADC module 12 (shown in FIG. 1) outputs bits having a number equal to or less than 6, only a few capacitors (e.g. 2 or 3) can be decreased in the SAR ADC module 12. Compared with conventional SAR ADC, the whole size of the ADC is nearly not changed. Thus, in a preferred embodiment, N is greater than 6, for example 8, 9, and 11.

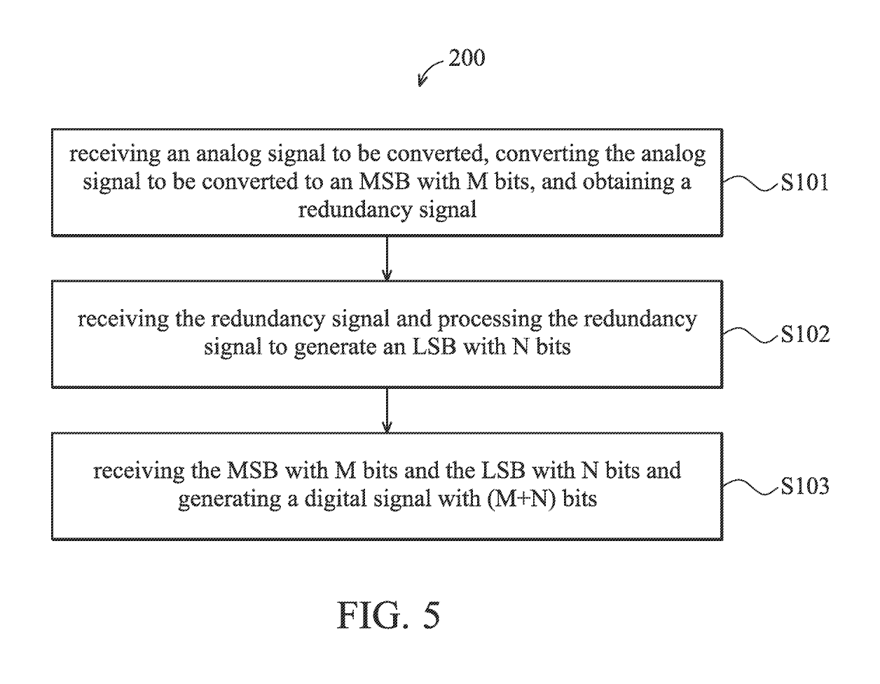

FIG. 5 shows an exemplary embodiment of an analog-to-digital conversion method. As shown in FIG. 5, an analog-to-digital conversion method 200 comprises the following steps:

Step S101: receiving an analog signal to be converted, and converting the analog signal to be converted to an MSB with M bits, and obtaining a redundancy signal;

Step S102: receiving the redundancy signal and processing the redundancy signal to generate an LSB with N bits;

Step S103: receiving the MSB with M bits and the LSB with N bits and generating a digital signal with (M+N) bits, wherein each of M and L is in a positive numerical value which can be integer or decimal fraction, and (M+N) is a positive integer.

According to the analog-to-digital conversion method 200, in the step of converting the analog signal to be converted to the MSB with M bits, M is equal to or greater than 2.

Further, according to the analog-to-digital conversion method 200, N is greater than 2.

In a preferred embodiment, N is greater than 6, for example 8, 9, and 11.

The above analog-to-digital conversion method 200 can be performed by any ADC described in the above embodiment, thus omitting the specific steps.

According to the analog-to-digital conversion method 200, by generating one or more MSBs by an MSB conversion module 11 before an SAR ADC module 12, an SAR ADC module 12 is required to generate only the LSB with N bits for a (M+N)-bit ADC. Thus, compared with the conventional SAD ADC, the number of capacitors used by the SAR ADC module is decreased to 2^{N} from 2^{N+M}, thereby achieving a high resolution analog-to-digital conversion and decreasing the size and cost of the ADC.

While the disclosure has been described by way of example and in terms of the preferred embodiments, it is to be understood that the disclosure is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An analog-to-digital converter comprising:
a most significant bit (MSB) conversion module for receiving an analog signal to be converted and converting the analog signal to an MSB with M bits, and for generating a redundancy signal;
a successive approximation register analog-to-digital converter (SAR ADC) module, coupled to the MSB conversion module, for receiving the redundancy signal and generating a least significant bit (LSB) with N bits in accordance with the redundancy signal; and
an operation module, coupled to the MSB conversion module and the SAR ADC module, for receiving the MSB with the M bits and the LSB with the N bits, and for generating a digital signal with (M+N) bits, wherein each of M and N is in a positive numerical value, and (M+N) is a positive integer.

2. The analog-to-digital converter as claimed in claim 1, wherein the MSB conversion module comprises:
a sub analog-to-digital converter (SUB ADC) for generating the MSB with at least two bits; and
a multiply digital-to-analog converter (MDAC), coupled to the SUB ADC, for generating the redundancy signal according to the MSB generated from the SUB ADC and the analog signal to be converted.

3. The analog-to-digital converter as claimed in claim 2, wherein the MDAC generates the redundancy signal by subtracting an analog voltage level corresponding to the MSB with M bits from the analog voltage to be converted.

4. The analog-to-digital converter as claimed in claim 2, wherein the SUB ADC is implemented by an SAR ADC, a flash ADC, or a sub-range ADC.

5. The analog-to-digital converter as claimed in claim 2, wherein the SAR ADC comprises:
an SAR logic circuit;
a capacitive digital-to-analog converters (CDAC) coupled to the SAR logic circuit; and
a comparator coupled to the SAR logic circuit and the CADC,
wherein the SAR logic circuit outputs a predetermined voltage to the CDAC and receives a comparison result output from the comparator, and the CDAC performs an operation with the redundancy signal from the MDAC and the predetermined voltage and output at least one operation result, and
wherein the comparator compares the operation results and a reference signal, to output a plurality of comparison results to the SAR logic circuit, the comparison results are converted to be the LSB with the N bits.

6. The analog-to-digital converter as claimed in claim 5, wherein an output terminal of the SAR logic circuit is coupled to the operation module for outputting the LSB with the N bits thereto, wherein 2^{N} capacitors are used by the CADC.

7. The analog-to-digital converter as claimed in claim 1, wherein the MSB conversion module comprises:
at least two stages each having a pipelined ADC,
wherein the pipelined ADC of each stage comprises:
a sub analog-to-digital converter (SUB ADC) generating a second digital signal with at least one bit; and
a multiply digital-to-analog converter (MDAC), coupled to the SUB ADC, for generating the redundancy signal according to the MSB with M bits generated from the SUB ADC and the

8. The analog-to-digital converter as claimed in claim 1, wherein the operation module is implemented by an adder-subtractor.

9. The analog-to-digital converter as claimed in claim 1, wherein M is equal to or greater than N.

10. The analog-to-digital converter as claimed in claim 1, wherein N is greater than 6.

11. An analog-to-digital conversion method comprising:
receiving an analog signal to be converted, and converting the analog signal to a most significant bit (MSB) with M bits, and generating a redundancy signal;
receiving the redundancy signal and processing the redundancy signal to generate a least significant bit (LSB) with N bits; and
receiving the MSB with M bits and the LSB with N bits and generating a digital signal with (M+N) bits, wherein each of M and N is positive, and (M+N) is a positive integer.

12. The analog-to-digital conversion method as claimed in claim 11, wherein in the step of converting the analog signal to be converted to the MSB with the M bits, M is equal to or greater than 2.

13. The analog-to-digital conversion method as claimed in claim 11, wherein N is greater than 6.

14. The analog-to-digital conversion method as claimed in claim 11, wherein in the step of converting the analog signal to the MSB with M bits, and for generating the redundancy signal comprises:
generating the MSB with at least two bits; and
generating the redundancy signal according to the MSB generated from the SUB ADC and the analog signal to be converted.

15. The analog-to-digital conversion method as claimed in claim 14, wherein in the step of generating a least significant bit (LSB) with N bits comprises:
performing an operation between the redundancy signal from the MDAC and the predetermined voltage and outputting at least one operation result; and
comparing a reference signal with the at least one operation result and outputting the comparison results which are further converted to be the LSB with the N bits.

16. An analog-to-digital converter comprising:
a first conversion module configured to receive an analog signal to be converted and convert the analog signal to a most significant bit (MSB) with M bits, and also configured to generate a redundancy signal according to the MSB and the analog signal;
a second conversion module, coupled to the first conversion module, and configured to receive the redundancy signal and generate a least significant bit (LSB) with N bits; and
an operation module, coupled to the first conversion module and the second conversion module, and configured to combine the MSB with the M bits and the LSB with the N bits to generate a digital signal with (M+N) bits, wherein each of M and N is positive, and (M+N) is a positive integer.
